(19) United States
(12) Patent Application Publication
(10) Pub. No.: US 2001/0011523 A1
(43) Pub. Date: Aug. 9, 2001

(54) Chemical vapor deposition apparatus

(75) Inventors: Jong Sung Paik, Seoul (KR); Soo Sik Yoon, Songnam-shi (KR); Jung Hwan Choi, Seoul (KR)

Correspondence Address: GEORGE C. BECK, FOLEY & LARDNER, P.O. Box 25696, 3000 K Street, N.W., Suite 500, Washington, DC, 20007-8696, US

(73) Assignee: Jusung Engineering Co., Ltd.

(21) Appl. No.: 09/770,285

(22) Filed: Jan. 29, 2001

(30) Foreign Application Priority Data
Feb. 9, 2000 (KR) 2000-6012

(51) Int. Cl. C23C 16/455

(52) U.S. Cl. 118/715

(57) ABSTRACT

A chemical vapor deposition apparatus comprising: a reaction chamber for defining an enclosed space; a pedestal arranged within the reaction chamber on which a substrate is settled; heater means arranged within the pedestal for heating the substrate; a gas inlet for introducing gas into the reaction chamber; a gas outlet for exhausting gas from the reaction chamber; and a gas injector extended from the end of the gas inlet, wherein the gas injector has a hollow side wall so that a heat exchanging medium can flow through the side wall, and inlet and outlet ports arranged in the outside of the sidewall, each of the inlet and outlet ports communicating with the inside of the side wall. Here, the outlet port is arranged higher than the inlet port. Also, the apparatus further comprises a partition for dividing the inside of the side wall of the gas injector with an inlet port side and an outlet port side, wherein the upper end of the partition does not reach the inner upper surface of the side wall whereby the heat exchanging medium can flow from the inlet port side to the outlet port side. According to the invention, only the temperature of the gas injector can be adjusted by circulating the heat exchange medium to the gas injector.

### BACKGROUND OF THE INVENTION

1. Field of the Invention

The invention relates to a chemical vapor deposition apparatus, and in particular, to a chemical vapor deposition apparatus supplying a reactant gas into a reaction chamber by using a gas injector.

2. Description of the Prior Art

Up to the present, most gas injector assemblies are adopting a showerhead method which supplies a gas into a reaction chamber by using a showerhead defined with a number of gas injecting pores for the uniformity of the gas injection.

Here, it is practically difficult to have a structure for circulating a heat exchanging medium around all of the pores to control the temperature of the showerhead. Therefore, the heat exchanging medium is circulated around the periphery of the showerhead only so that the central part of the showerhead can be indirectly temperature controlled under the influence of the periphery. Accordingly, the central part has a temperature band different from the periphery and deficient of direct heat exchanging capability, and thus temperature control is actually difficult in the case of thermal transmission from a heat generator mounted on a pedestal and so on. Furthermore, considering that the diameter of the reaction chamber increases according as wafers having larger diameters, such an area out of temperature control will be increased inevitably and gradually, which is not preferable.

Meanwhile, as the integrity of a semiconductor device increases, more enhanced film property is being required. This requirement can be obtained by supplying a vaporized liquid state or solid state reactant source into the reaction chamber rather than simply using a gaseous reactant source. An MOCVD process is exemplary of such a case. Here, it is required that the temperature of the reaction chamber and each component therein can be correctly controlled since an organic metal reactant source creates various reactions according to temperature range.

For example, in forming a thin film according to the MOCVD process, a condensation takes place in a low temperature area to obstruct the reactant source supply or induce undesired particles, and a decomposition takes place in a high temperature area so that the reactant source degrades to decrease deposition rate or deteriorate quality of the deposited film. Furthermore, in order to avoid the chemical vapor deposition on unwanted parts such as a chamber wall or gas injector assembly and to cause the chemical vapor deposition on wanted parts such as a substrate, the temperature of the reaction chamber and each component therein should be correctly controlled.

In such a temperature control, especially the temperature control in the gas injector assembly should be performed within the range in which the uniformity of the gas injection may not be damaged, and is one of the most difficult techniques since consideration should be carried out on the heat influence released from the heat generator mounted on the pedestal and so on.

### SUMMARY OF THE INVENTION

The invention is proposed to solve the foregoing problems and it is therefore an object of the invention to provide a chemical vapor deposition apparatus in which a showerhead is replaced with a gas injector unit where a heat exchanging medium can flow.

To obtain the foregoing object of the invention, it is provided a chemical vapor deposition apparatus comprising: a reaction chamber for defining an enclosed space; a pedestal arranged within said reaction chamber on which a substrate is settled; heater means arranged within said pedestal for heating said substrate; a gas inlet for introducing gas into said reaction chamber; a gas outlet for exhausting gas from said reaction chamber; and a gas injector extended from the end of said gas inlet, wherein said gas injector has a hollow side wall so that a heat exchanging medium can flow through said side wall, and inlet and outlet ports arranged in the outside of said sidewall, each of said inlet and outlet ports communicating with the inside of said side wall. Here, the outlet port is arranged higher than said inlet port.

Also, the apparatus further comprises a partition for dividing the inside of said side wall of the gas injector with an inlet port side and an outlet port side, wherein the upper end of said partition does not reach the inner upper surface of said side wall whereby the heat exchanging medium can flow from said inlet port side to said outlet port side.

### BRIEF DESCRIPTION OF THE DRAWINGS

Hereinafter, preferred embodiment of the invention will be described in reference to the appended drawings, wherein:

FIG. 1 is a schematic view for illustrating a chemical vapor deposition apparatus according to the invention; and

FIG. 2A and FIG. 2B are schematic views for illustrating a gas injector provided according to the invention.

### DESCRIPTION OF THE PREFERRED EMBODIMENT

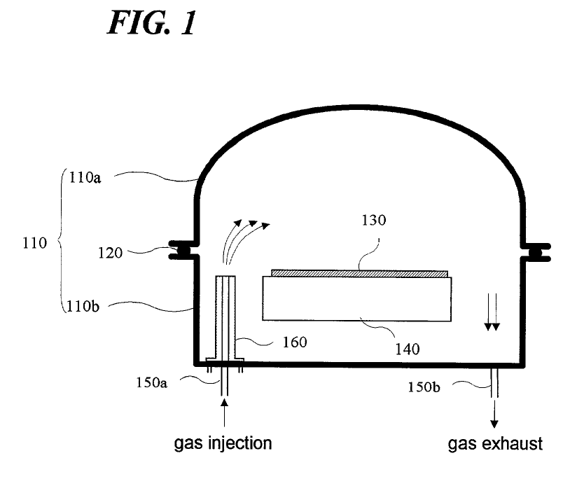

FIG. 1 is a schematic view for illustrating a chemical vapor deposition apparatus according to the invention.

Referring to FIG. 1, the reaction space sealed from the outside is provided by the reaction chamber 110. The reaction chamber 110 is comprised of an upper chamber 110a and a lower chamber 110b, which are coupled with flanges. The upper chamber 110a has the shape of a dome for uniform distribution of a reactant gas.

For effective sealing of the reaction space from the outside, an O-ring 120 is inserted between the flanges of the upper and lower reaction chambers 110a and 110b.

A pedestal is arranged within the reaction chamber 110 on which a substrate 130 is settled, and a heater means (not shown) is arranged within the pedestal 140.

The reactant gas is supplied into the reaction chamber 110 through a gas inlet 150a, and injected into the chamber 110 through a gas injector 160 extended to the end of the gas inlet 150a. The reactant gas injected like this collides against the inner wall of the dome shaped upper reaction chamber 110a and is uniformly distributed in the reaction space. The reactant gas in the reaction chamber 110 is exhausted out through a gas outlet 150b by a vacuum pump (not shown).

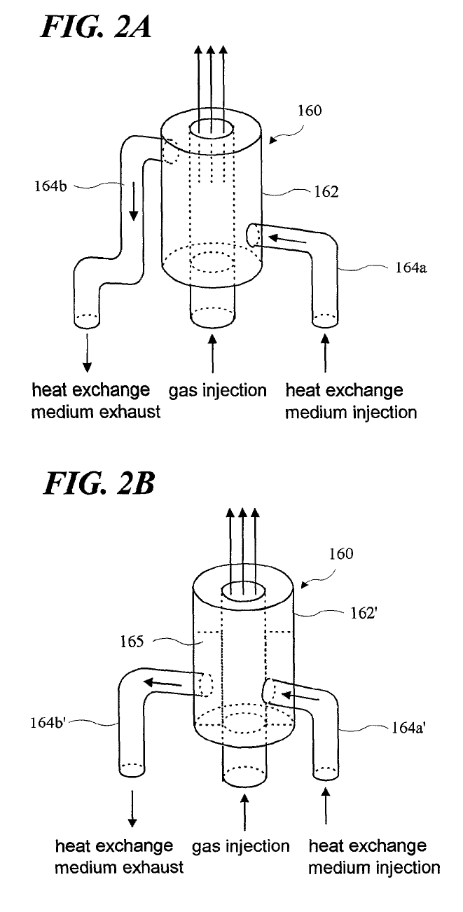

FIG. 2A is a schematic view for illustrating an example of the gas injector according to the invention.

Referring to FIG. 2A, the gas injector 160 has a side wall 162 which is hollow so that a heat exchanging medium can flow through it. In the outside of the side wall 162 of the gas injector 160, heat exchanging medium inlet and outlet ports 164a and 164b are provided to communicate with the hollow space of the side wall 162. The heat exchanging medium is introduced through the inlet port 164a, circulates around the hollow space within the side wall 162, and then is exhausted through the outlet port 164b. The heat exchanging medium can be liquid or gas.

In order to effectively control the temperature of the gas injector 160, it is required that the heat exchanging medium fills the inner space of the gas injector side wall 162 as more as possible before exhaustion. Therefore, the outlet port 164 is preferably arranged higher than the inlet port 164a.

FIG. 2B is a schematic view for illustrating another example of the gas injector.

Referring to FIG. 2B, the gas injector 160 has a side wall 162′ which is hollow so that the heat exchanging medium can flow through it. In the outside of the side wall 162′ of the gas injector 160, heat exchanging medium inlet and outlet ports 164a′ and 164b′ are provided to communicate with the hollow space of the side wall 162′.

A partition 165 is vertically arranged within the inner space of the gas injector side wall 162′ so that the inner space thereof can be divided into two parts, i.e., a inlet port side and an outlet port side. Here, it is designed that the upper end of the partition 165 does not reach the inner upper surface of the side wall 162′. Therefore, the heat exchanging medium introduced through the inlet port 164a′ fills the inlet port side of the inner space until reaches the upper end of the partition 165, and then overflows into the outlet port side.

The concept of circulating the heat exchanging medium through the gas injector is applied to the upper and lower chambers 110a and 110b in the same manner. In other words, each of the upper and lower chambers 110a and 110b can has a flow path for circulating the heat exchanging medium through the same. In this case, it is preferable to design the flow path so that the circulations of the heat exchanging media can be mutually connected, and thus the gas injector 160 and the upper and lower reaction chambers 110a and 110b can share a same heat exchanger.

As described hereinbefore according to the chemical vapor deposition of the invention, the temperature of the gas injector 160 can be separately controlled by circulating the heat exchanging medium through the gas injector. Also, the flow path of the heat exchanging medium is integrated into the gas injector and thus any additional equipment for the heat exchange is excluded. Alternatively, the heat exchanger used for heat exchange of the upper and lower reaction chambers can be used for the injector at the same time so that the installation thereof is very easy and the cost can be reduced in a great amount.

While the invention has been described in reference to the preferred embodiments and the appended drawings, it is apparent to those skilled in the art that various modifications, changes and equivalents can be made without departing from the scope of the invention.

What is claimed is:

1. A chemical vapor deposition apparatus comprising:
a reaction chamber for defining an enclosed space;
a pedestal arranged within said reaction chamber on which a substrate is settled;
heater means arranged within said pedestal for heating said substrate;
a gas inlet for introducing gas into said reaction chamber;
a gas outlet for exhausting gas from said reaction chamber; and
a gas injector extended from the end of said gas inlet, wherein said gas injector has a hollow side wall so that a heat exchanging medium can flow through said side wall, and inlet and outlet ports arranged in the outside of said sidewall, each of said inlet and outlet ports communicating with the inside of said side wall.

2. A chemical vapor deposition apparatus in accordance with claim 1, wherein said outlet port is arranged higher than said inlet port.

3. A chemical vapor deposition apparatus in accordance with claim 1, further comprising a partition for dividing the inside of said side wall of the gas injector with an inlet port side and an outlet port side, wherein the upper end of said partition does not reach the inner upper surface of said side wall whereby the heat exchanging medium can flow from said inlet port side to said outlet port side.
